(19) United States
(12) Patent Application Publication
(10) Pub. No.: US 2012/0049916 A1
(43) Pub. Date: Mar. 1, 2012

(54) CALIBRATION METHOD FOR OSCILLATION FREQUENCY AND CALIBRATION DEVICE FOR OSCILLATION FREQUENCY

(75) Inventors: SUNG-TA TSAI, JIAOXI TOWNSHIP (TW); HUANG-CHIN CHANG, ZHONGHE CITY (TW); CHING-FENG HSIEH, TAIPEI CITY (TW)

(73) Assignee: ASKEY COMPUTER CORP., TAIPEI (TW)

(21) Appl. No.: 12/916,837

(22) Filed: Nov. 1, 2010

(30) Foreign Application Priority Data
Aug. 27, 2010 (TW) 099128845

(51) Int. Cl. H03L 7/00

(52) U.S. Cl. 327/160

(57) ABSTRACT

A calibration method for oscillation frequency and a calibration device embodying the calibration method are used to calibrate oscillation frequency of an electronic product, including steps of receiving radio time signals transmitted from a radio broadcast station and transforming the radio time signals into multiple pulse signals; calculating the pulse signals and clock signals corresponding to the oscillation frequency to generate a corresponding control signal; and using the control signal to adjust the clock signals generated by an adjustable frequency generating unit in the electronic product so as to calibrate the oscillation frequency corresponding to the clock signals.

### CROSS-REFERENCE TO RELATED APPLICATION

This non-provisional application claims priority under 35 U.S.C. §119(a) on Patent Application No(s). 099128845 filed in Taiwan, R.O.C. on Aug. 27, 2010, the entire contents of which are hereby incorporated by reference.

### FIELD OF THE TECHNOLOGY

The present invention relates generally to a calibration method and device for oscillation frequency, and more particularly to a calibration method and device for oscillation frequency for easily and precisely calibrating the oscillation frequency of an electronic product.

### BACKGROUND

It is known that clock signals are critical in operation of an electronic product. This is because the clock signals (also referred to as oscillation frequency) are the basic time reference for the operation of the electronic product. Moreover, an internal processing unit and other units of the electronic product must rely on precise clock signals to precisely perform communication and data transmission operation. For example, in data transmission between multiple apparatuses, the synchronism between the apparatuses must be first achieved via the clock signals. Only in this case, the data can be truly synchronously transmitted between the apparatuses. The clock signals are more important when the communication and data transmission operation is performed between the electronic product and external peripheral devices. Conclusively, it is critical for an electronic product to operate on the basis of precise clock signals.

In general, the clock signals and the corresponding oscillation frequency of an electronic product are generated by an oscillator in a clock signal generator or so-called “frequency generator”. The stability of the clock signals output from the clock signal generator is affected by factors of temperature, duration of use, environment, noise, etc. These factors may cause the clock signal generator (or frequency generator) to generate imprecise clock signals (or oscillation frequency) with time (or frequency) shift or delay.

Conventionally, the oscillator is replaced with a precision oscillator to generate precise clock signals for solving the above problem. However, the use of the precision oscillator leads to an increase of the cost incurred in using the clock signal generator.

On the other hand, in order to ensure that the clock signals are continuously and precisely output, the precision oscillator must cooperate with the time signals of Internet time protocol, such as NTP, IEEE 1588, GPS or TV, to dynamically calibrate the oscillation frequency. For example, U.S. Pat. No. 7,236,126 B2 discloses an AGPS system using NTP server and a method for determining the location of a terminal using a NTP server. According to the above patent, the time is calibrated to achieve time synchronization by means of the time information provided by network time protocol. However, the electronic product must access the Internet first to utilize the network time protocol. This is obviously inconvenient to those electronic products without Internet access function. Therefore, the application of network time protocol is quite limited.

Therefore, the present invention provides a calibration method and device for oscillation frequency, which can quickly and precisely calibrate the oscillation frequency corresponding to the clock signals at low costs.

### SUMMARY

An objective of the present invention is to provide a calibration method for calibrating oscillation frequency of an electronic product.

A further objective of the present invention is to provide a calibration device for precisely calibrating oscillation frequency of an electronic product.

According to the above and other objectives, the calibration method for oscillation frequency of the present invention is used to calibrate oscillation frequency of an electronic product. The electronic product has an adjustable frequency generating unit for generating clock signals corresponding to the oscillation frequency. The calibration method includes steps of: receiving radio time signals transmitted from a radio broadcast station and transforming the radio time signals into multiple pulse signals corresponding to the radio time signals; calculating the pulse signals and the clock signals to generate a corresponding control signal; and using the control signal to adjust the clock signals generated by the adjustable frequency generating unit so as to calibrate the corresponding oscillation frequency.

Still according to the above and other objectives, the calibration device for oscillation frequency of the present invention is applicable to reception of radio time signals transmitted from a radio broadcast station and configured to calibrate oscillation frequency of an electronic product. The calibration device includes a radio receiving unit, an adjustable frequency generating unit and a processing unit. The radio receiving unit has an antenna for receiving the radio time signals and a signal processing circuit for transforming the radio time signals into multiple pulse signals. The adjustable frequency generating unit serves to generating clock signals corresponding to the oscillation frequency. The processing unit is coupled with the radio receiving unit and the adjustable frequency generating unit. The processing unit serves to receive the clock signals and calculate the number of the clock signals generated within the length of time of the pulse signals to generate the corresponding control signal. The processing unit also serves to use and feed back the control signal to adjust the clock signals generated by the adjustable frequency generating unit so as to calibrate the corresponding oscillation frequency.

In comparison with the prior art, by means of the calibration method and device for oscillation frequency of the present invention, the clock signals generated by the adjustable frequency generating unit of an electronic product corresponding to the oscillation frequency can still be precisely calibrated without using any precision oscillator or utilizing any standard protocol of the Internet.

### BRIEF DESCRIPTION OF THE DRAWINGS

The structure and the technical means adopted by the present invention to achieve the above and other objectives can be best understood by referring to the following detailed description of the preferred embodiments and the accompanying drawings, wherein:

FIG. 1 is a flow chart of a preferred embodiment of the calibration method for oscillation frequency of the present invention; and

FIG. 2 is a diagram showing the relationship between the pulse signals and clock signals; and

FIG. 3 is a block diagram of a preferred embodiment of the calibration device for oscillation frequency of the present invention.

### DETAILED DESCRIPTION

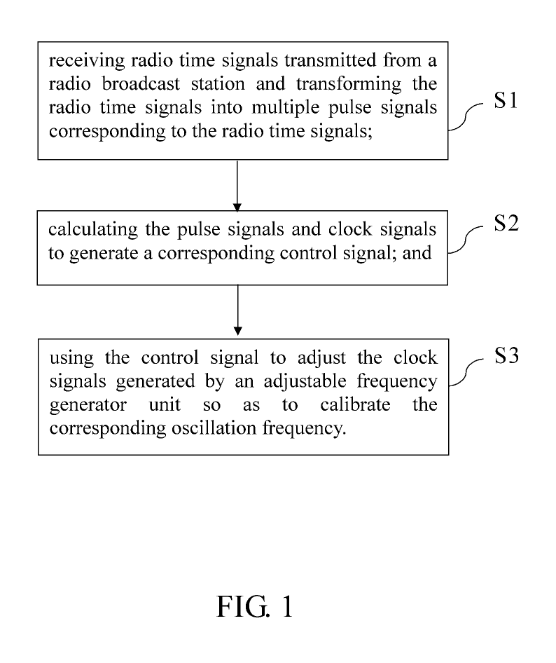

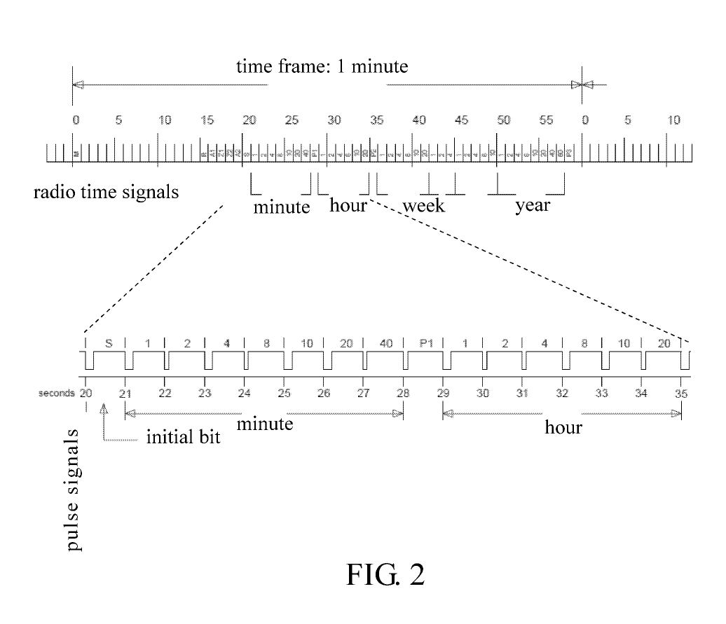

Please refer to FIG. 1, which is a flow chart of a preferred embodiment of the calibration method for oscillation frequency of the present invention. In this embodiment, the calibration method is used to calibrate the oscillation frequency of an electronic product. The electronic product has an adjustable frequency generating unit for generating clock signals corresponding to the oscillation frequency. The calibration method of the present invention includes a first step S1 of receiving and transforming radio time signals transmitted from a radio broadcast station to generate multiple corresponding pulse signals. For example, the radio time signals contain time messages related to minute, hour, week, and year. The pulse signals also contain the above time messages and provide an initial bit for identification of the time signals as shown in FIG. 2.

The radio broadcast station transmits the radio time signals by the Japan-based time signal station JJY, China-based time signal station BPC, China-based long-wave time transmission station BPL, Germany-based longwave time signal and standard-frequency radio station DCFF77, British VLF transmitter GBZ, Swiss low frequency time signal transmitter HBG, British time signal station MSF, Russian time signal station RBU, time signal transmitter RAB99 based in Khabarovsk Russia, Russian time signal station RJH-63, time signal station RJH-69 based in Belarus, time signal station RJH-77 in Belarus, Russian time signal station RJH-86, Russian time signal station RJH-90, time signal station RTZ based in Siberia, Tele Diffusion de France (TDF), the US-based WWVB, Japanese time signal station JG2AS, or Czech time signal station OMA.

The calibration method of the present invention further includes a second step S2 of calculating the pulse signals and the clock signals to generate a corresponding control signal. The control signal is a voltage level. The clock signals generated by the adjustable frequency generating unit can be adjusted by varying the voltage level. It should be noted that the voltage level is varied to adjust the capacitance of the varactor of the adjustable frequency generating unit so as to adjust the clock signals corresponding to the oscillation frequency.

In an embodiment of the present invention, calculation of the pulse signals and the clock signals requires calculating the number of the clock signals generated within the length of time of the pulse signals to obtain the corresponding control signal. For example, as shown in FIG. 2, in the time frame of the radio time signals, the length of time is set to one minute, which is further divided to thereby consist of the 0^{th} second through 59^{th} second. Correspondingly, there are 0-59 pulse signals to represent the length of time of the radio time signals. That is, each pulse signal represents one second. Accordingly, as exemplified by “minute”, if the “minute” is composed of seven pulse signals, then the seven pulse signals are used to calculate the length of time, which is seven seconds. By calculating the number of the corresponding clock signals generated within the length of time, it can be further judged whether the clock signals are precise. For example, if the number of the generated clock signals is also seven, this means that the length of time of clock signals is also seven seconds. On the contrary, if the number of the generated clock signals is larger or smaller than seven, this means that the clock signals are generated earlier or later than expected. Then, the corresponding control signal is generated and output, depending on whether the clock signals are generated earlier or later than expected.

The calibration method of the present invention further includes a third step S3 of using the control signal to adjust the clock signals generated by the adjustable frequency generating unit so as to calibrate the corresponding oscillation frequency. For example, by varying the voltage level of the control signal, the capacitance of the varactor of the adjustable frequency generating unit can be adjusted so as to adjust the clock signals corresponding to the oscillation frequency. Accordingly, the oscillation frequency can be calibrated.

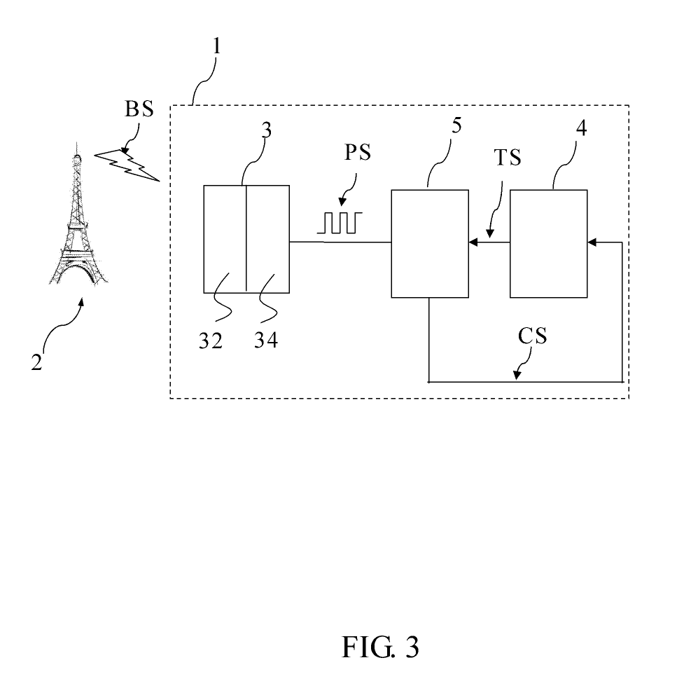

Please refer to FIG. 3, which is a block diagram of a preferred embodiment of a calibration device for oscillation frequency of the present invention. As shown in the drawing, a calibration device 1 for oscillation frequency is applicable to reception of the radio time signals BS transmitted from a radio broadcast station 2 and configured to calibrate the oscillation frequency of an electronic product. The calibration device 1 includes a radio receiving unit 3, an adjustable frequency generating unit 4 and a processing unit 5. The radio broadcast station 2 transmits the radio time signals BS by JJY, BPC, BPL, DCFF77, GBZ, HBG, MSF, RBU, RAB99, RJH-63, RJH-69, RJH-77, RJH-86, RJH-90, RTZ, TDF, WWVB, JG2AS or OMA. In general, the radio broadcast station 2 transmits the radio time signals BS with standard time signals according to a cesium atomic clock.

The radio receiving unit 3 has an antenna 32 for receiving the radio time signals BS and a signal processing circuit 34 for transforming the radio time signals BS into multiple pulse signals PS as shown in FIG. 2.

The adjustable frequency generating unit 4 generates the clock signals TS corresponding to the oscillation frequency. The adjustable frequency generating unit 4 includes a varactor VC with a capacitance controlled by the voltage level. Via the voltage level, a reverse bias voltage can be applied to the varactor VC. When the reverse bias voltage applied to the varactor VC increases, the distance between the surfaces of the conductors in the varactor VC is lengthened, that is, the capacitance is decreased. Under such circumstance, the generation rate of the clock signals is decreased. Conversely, when the reverse bias voltage applied to the varactor VC decreases, the distance between the surfaces of the conductors in the varactor VC is shortened, that is, the capacitance is increased. Under such circumstance, the generation rate of the clock signals is increased. Accordingly, by varying the voltage level, the clock signals TS output from the adjustable frequency generating unit 4 can be adjusted. The varactor VC can be, for example, a junction diode, a standard-mode MOS varactor, an inversion-mode MOS varactor or an accumulation-mode MOS varactor.

The processing unit 5 is coupled with the radio receiving unit 3 and the adjustable frequency generating unit 4. The processing unit 5 is used to receive the clock signals TS and calculate the number of the clock signals TS generated within the length of time of the pulse signals PS to generate the corresponding control signal CS. Also, the processing unit 5 is used to feed back the control signal CS to adjust the clock signals TS generated by the adjustable frequency generating unit 4 so as to calibrate the corresponding oscillation frequency of the electronic product. For example, the control signal CS can be a voltage level. The voltage level is varied according to the calculated number of the clock signals TS generated within the length of time of the pulse signals PS, and fed back to adjust the clock signals TS generated by the adjustable frequency generating unit 4, so as to calibrate the corresponding oscillation frequency.

In comparison with the prior art, with the calibration method and device for oscillation frequency of the present invention, the clock signals generated by the adjustable frequency generating unit of an electronic product corresponding to the oscillation frequency can still be precisely calibrated without using any precision oscillator or utilizing any standard protocol of the Internet.

The above embodiments are only used to illustrate the present invention, but are not intended to limit the scope thereof. It is understood that many changes and modifications of the above embodiments can be made without departing from the spirit of the present invention. Therefore, the scope of the present invention should be defined by the appended claims.

What is claimed is:

1. A calibration method for oscillation frequency, the calibration method being used to calibrate oscillation frequency of an electronic product, the electronic product having an adjustable frequency generating unit for generating clock signals corresponding to the oscillation frequency, the method comprising the steps of:
receiving radio time signals transmitted from a radio broadcast station and transforming the radio time signals into multiple pulse signals corresponding to the radio time signals;
calculating the pulse signals and the clock signals to generate a corresponding control signal; and
using the control signal to adjust the clock signals generated by the adjustable frequency generating unit so as to calibrate the corresponding oscillation frequency.

2. The method as claimed in claim 1, wherein, in the step of calculating the pulse signals and the clock signals, the number of the clock signals generated within the length of time of the pulse signals is calculated.

3. The method as claimed in claim 1, wherein the control signal is a voltage level, such that the clock signals generated by the adjustable frequency generating unit can be adjusted by variation of the voltage level.

4. The method as claimed in claim 3, wherein a capacitance of a varactor of the adjustable frequency generating unit is adjusted by variation of the voltage level, and the clock signals corresponding to the oscillation frequency are adjusted by variation of the capacitance.

5. The method as claimed in claim 1, wherein the radio broadcast station transmits the radio time signals by JJY, BPC, BPL, DCFF77, GBZ, HBG, MSF, RBU, RAB99, RJH-63, RJH-69, RJH-77, RJH-86, RJH-90, RTZ, TDF, WWVB, JG2AS or OMA.

6. A calibration device for oscillation frequency, the device being applicable to reception of radio time signals transmitted from a radio broadcast station and configured to calibrate oscillation frequency of an electronic product, the device comprising:
a radio receiving unit having an antenna for receiving the radio time signals and a signal processing circuit for transforming the radio time signals into multiple pulse signals;
an adjustable frequency generating unit for generating clock signals corresponding to the oscillation frequency; and
a processing unit coupled with the radio receiving unit and the adjustable frequency generating unit, configured to receive the clock signals and calculate the number of the clock signals generated within the length of time of the pulse signals to generate the corresponding control signal, and configured to feed back the control signal to thereby adjust the clock signals generated by the adjustable frequency generating unit so as to calibrate the corresponding oscillation frequency.

7. The device as claimed in claim 6, wherein the control signal is a voltage level, the voltage level being varied according to the calculated number of the clock signals generated within the length of time of the pulse signals.

8. The device as claimed in claim 6, wherein the adjustable frequency generating unit includes a varactor with a capacitance controlled by the voltage level.

9. The device as claimed in claim 8, wherein the varactor is selected from the group consisting of a junction diode, a standard-mode MOS varactor, an inversion-mode MOS varactor and an accumulation-mode MOS varactor.

10. The device as claimed in claim 6, wherein the radio broadcast station transmits the radio time signals by JJY, BPC, BPL, DCFF77, GBZ, HBG, MSF, RBU, RAB99, RJH-63, RJH-69, RJH-77, RJH-86, RJH-90, RTZ, TDF, WWVB, JG2AS or OMA.
